(19) United States
(12) Patent Application Publication
(10) Pub. No.: US 2018/0005816 A1
(43) Pub. Date: Jan. 4, 2018

(54) SEMICONDUCTOR LAMINATE

(71) Applicant: Sumitomo Electric Industries, Ltd., Osaka-shi (JP)

(72) Inventors: Kenji Kanbara, Itami-shi (JP); Keiji Wada, Itami-shi (JP); Tsubasa Honke, Itami-shi (US)

(21) Appl. No.: 15/542,821

(22) PCT Filed: Jun. 23, 2015
(86) PCT No.: PCT/JP2015/067999

§ 371 Date: Jul. 11, 2017

(30) Foreign Application Priority Data
Jan. 13, 2015 (JP) 2015-004423

(51) Int. Cl. H01L 21/02; C30B 29/36; H01L 29/16; C30B 25/20; H01L 29/36; H01L 29/34

(52) U.S. Cl. CPC H01L 21/0243; H01L 29/36; H01L 29/34; H01L 29/1608; C30B 25/20; H01L 21/02529; H01L 21/02378; C30B 29/36; H01L 21/0262

(57) ABSTRACT

A semiconductor laminate includes a silicon carbide substrate having a first main surface and a second main surface opposite the first main surface, and an epitaxial layer composed of silicon carbide disposed on the first main surface. The second main surface has an average value of roughness Ra of 0.1 μm or more and 1 μm or less with a standard deviation of 25% or less of the average value.

### TECHNICAL FIELD

The present disclosure relates to a semiconductor laminate.

### BACKGROUND ART

A technique in which an epitaxial layer composed of silicon carbide is disposed on a silicon carbide (SiC) substrate is known (for example, refer to PTL 1).

### CITATION LIST

### Patent Literature

PTL 1: Japanese Unexamined Patent Application Publication No. 2013-34007

### SUMMARY OF INVENTION

A semiconductor laminate according to the present disclosure includes a silicon carbide substrate having a first main surface and a second main surface opposite the first main surface, and an epitaxial layer composed of silicon carbide disposed on the first main surface. The second main surface has an average value of roughness Ra of 0.1 μm or more and 1 μm or less with a standard deviation of 25% or less of the average value.

### BRIEF DESCRIPTION OF DRAWINGS

FIG. 1 is a schematic cross-sectional view showing a structure of a semiconductor laminate.

FIG. 2 is a flowchart schematically showing a method of producing a semiconductor laminate.

FIG. 3 is a schematic cross-sectional view for illustrating a method of producing a semiconductor laminate.

FIG. 4 is a schematic perspective view showing a structure of a holder.

### DESCRIPTION OF EMBODIMENTS

Studies by the present inventors have shown that even when epitaxial layer is of a high quality, regarding a semiconductor device manufactured by using a semiconductor laminate including the epitaxial layer disposed on a silicon carbide substrate, device characteristics may be degraded or the manufacturing yield may be decreased in some cases. More specifically, in processes of manufacturing a semiconductor device by using a semiconductor laminate, accuracy in the process of photolithography may be decreased, which may cause variations in characteristics of the resulting semiconductor devices and a decrease in the yield. The present inventors have found that it is possible to suppress the occurrence of the problems described above by setting, in predetermined ranges, the average value and variation of the roughness of a main surface (backside surface) of a silicon carbide substrate opposite a main surface on which an epitaxial layer is disposed, to which attention is usually not paid. Specifically, by setting the average value of roughness Ra of the backside surface to be 0.1 μm or more and 1 μm or less and the standard deviation to be 25% or less of the average value, it is possible to suppress the occurrence of the problems described above.

Furthermore, in a vertical type semiconductor device in which an electric current flows in the thickness direction of a silicon carbide substrate, the contact resistance of a backside electrode may be increased in some oases. Specifically, when a semiconductor device which includes a backside electrode disposed on a backside surface of a silicon carbide substrate is manufactured, a step of forming an ohmic junction between the backside electrode and the backside surface is provided. In the step of forming an ohmic unction, laser annealing may be used in some cases. By setting the average value of roughness Ra of the backside surface to be 0.1 μm or more and 1 μm or less and the standard deviation to be 25% or less of the average value, it is possible to suppress a variation in heat absorption during laser annealing. Consequently, uniformity in the ohmic junction between the backside surface and the electrode is improved. That is, an increase in the contact resistance of the backside electrode is suppressed.

In a semiconductor laminate according to the present disclosure, the average value of roughness Ra of the backside surface is 0.1 μm or more and 1 μm or less, and the standard deviation is 25% or less of the average value. In accordance with the present disclosure, it is possible to provide a semiconductor laminate that is able to stably impart excellent characteristics to a semiconductor device in which silicon carbide is used as a material

The average value of roughness of the backside surface (second main surface) and the standard deviation, for example, can be checked as described below. The arithmetic average roughness (Ra) of the backside surface is measured a plurality of times, and the average value of the measured values and the standard deviation are calculated. The measurement can be performed linearly from the center of the backside surface in the radial direction. A region within 3 mm from the outer circumference of the backside surface is excluded from the measurement target. The measurement distance for each measurement is, for example, 400 μm. When first measurement is started from the center of the backside surface and completed for a measurement distance of 400 μm, next measurement is performed, for example, at an interval of 10 mm in the radial direction with a measurement distance of 400 μm. This process is repeated until the measured region reaches the region within 3 mm from the outer circumference of the backside surface. Then, the average value and standard deviation in the entire backside surface are calculated from a plurality of roughness (Ra) values that have been obtained. In order to measure the roughness, for example, a laser microscope can be used. As the laser microscope, for example, a VK-8700 or VK-9700 manufactured by Keyence Corporation may be used. In using such a laser microscope, the magnification of the objective lens is preferably about 5 times.

The semiconductor laminate may have a bow of more than 0 μm and 10 μm or less when the first main surface is placed upward. In order to measure the bow, for example, a FlatMaster manufactured by TROPEL Corporation may be used. In the FlatMaster, a region excluding the region within 3 mm from the outer circumference of the semiconductor laminate is measured. More specifically, the entire surface of the measurement region is irradiated with laser light at one time, and information on the difference in level of the surface of the semiconductor laminate is detected as interference fringes. In the measuring apparatus, the least squares plane is set as a reference plane, and the difference between the central part of the semiconductor laminate and the reference plane is calculated as a bow. When the surface to be measured is placed downward, in the case where the bow value is positive, the semiconductor laminate has an upward convex shape. On the other hand, in the case where the how value is negative, the semiconductor laminate has a downward convex shape. The semiconductor laminate having a how of more than 0 μm and 10 μm or less when the first main surface is placed upward is advantageous as described below.

Manufacturing processes for a semiconductor device include steps of heating at semiconductor laminate. Examples thereof include a baking step of photolithography plasma CVD, and high-temperature ion implantation. In these steps, the semiconductor laminate is placed, with the frontside surface facing upward, on a heated stage or susceptor. Accordingly, in these steps, the semiconductor laminate is heated from the backside surface side. When the surface roughness of the backside surface of the semiconductor laminate is uniform and the bow is more than 0 μm and 10 μm or less, deformation due to heating can be suppressed. Therefore, it is possible to suppress process variations due to deformation of the semiconductor laminate in manufacturing processes for a semiconductor device.

The diameter of the semiconductor laminate may be 75 mm or more. The problems described above occur particularly markedly in a large-diameter substrate. Therefore, the semiconductor laminate according to the present disclosure is suitable for use in a semiconductor laminate with a diameter of 75 mm or more. The diameter of the semiconductor laminate may be 100 mm or more, 150 mm or more, or 200 mm or more.

In the semiconductor laminate, the substrate and the epitaxial layer each may contain an impurity that generates majority carriers, and the concentration of the impurity in the substrate may be higher than the concentration of the impurity in the epitaxial layer. Such a semiconductor laminate is suitable for use in manufacturing a vertical-type semiconductor device. Some of the problems described above occur markedly in the manufacture of a vertical-type semiconductor device. Therefore, the semiconductor laminate according to the present disclosure is suitable for use n a semiconductor laminate in which the impurity concentration in the substrate is higher than that in the epitaxial layer.

### [Detailed Description of Embodiments]

An embodiment of a semiconductor laminate according to the present disclosure will be described below with reference to the drawings. In the drawings below, the same reference numerals denote identical or corresponding parts, and repeated descriptions may be omitted in some cases.

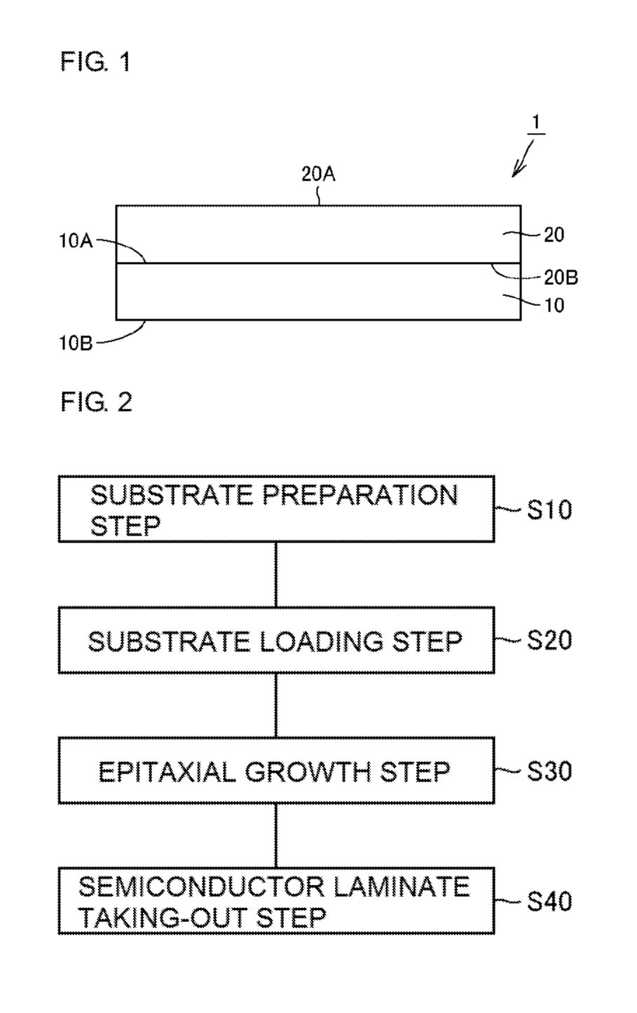

Referring to FIG. 1, a semiconductor laminate 1 in this embodiment is disk-shaped and includes a silicon carbide substrate 10 and an epitaxial layer 20 which is formed by epitaxial growth on a first main surface 10A of the silicon carbide substrate 10 and composed of silicon carbide. The diameter of the semiconductor laminate 1 is, for example, 75 mm. The diameter of the semiconductor laminate 1 may be 100 mm or more, 150 mm or more, or 200 mm or more.

The silicon carbide substrate 10 contains an n-type impurity, such as nitrogen (N), and the conductivity type of the silicon carbide substrate 10 is n-type. The epitaxial layer 20 contains an n-type impurity, such as nitrogen (N), and the conductivity type of the epitaxial layer 20 is n-type. The concentration of the n-type impurity in the silicon carbide substrate 10 is higher than the concentration of the n-type impurity in the epitaxial layer 20. The impurity concentration in the silicon carbide substrate 10 is, for example, 5.0×10¹⁸ to 2.0×10¹⁹ cm⁻³. The impurity concentration in the epitaxial layer 20 is, for example, 1.0×10¹⁵ to 1.0×10¹⁶ cm⁻³. The impurity concentration in each of the silicon carbide substrate 10 and the epitaxial layer 20 can be measured, for example, by secondary ion mass spectrometry (SIMS) in the wafer thickness direction.

When a semiconductor device is manufactured by using the semiconductor laminate 1, for example, a p-type impurity, such as aluminum (Al) or boron (B), and an n-type impurity, such as phosphorus (P), are introduced into the epitaxial layer 20 to form impurity regions (not shown). A resist layer (not shown) is formed on a second main surface 20A opposite a first main surface 20B of the epitaxial layer 20 in contact with the silicon carbide substrate 10, a mask layer (not shown) is formed by a photolithographic process, and then by performing ion implantation or the like, an impurity region having a desired shape is formed. Furthermore, electrodes (not shown) are formed on the second main surface 20A of the epitaxial layer 20 and a second main surface 10B of the silicon carbide substrate 10. As described above, by forming impurity regions and electrodes on the semiconductor laminate 1, a semiconductor device is manufactured.

In the semiconductor laminate 1 according to this embodiment, the average value of roughness Ra of the second main surface 10B of the silicon carbide substrate 10 is 0.1 μm or more and 1 μm or less, and the standard deviation is 25% or less of the average value. By setting not only the average value of roughness of the second main surface 10B (backside surface) of the silicon carbide substrate 10 but also the variation of the roughness in such ranges, in the semiconductor laminate according to this embodiment, it is possible to suppress the occurrence of problems, as a decrease in accuracy in the process of photolithography and/or an increase in contact resistance of the backside electrode and/or degradation in die bonding reliability.

### [Method of Producing Semiconductor Laminate 1]

Referring to FIG. 2, in a method of producing a semiconductor laminate 1 according to this embodiment, first, as a step (S10), a substrate preparation step is carried out. In the step (S10), for example, by slicing an ingot composed of 4H—SiC containing an n-type impurity at a desired concentration, a disk-shaped silicon carbide substrate 10 is prepared. The diameter of the silicon carbide substrate 10 is, for example, 100 mm. The thickness of the silicon carbide substrate 10 is, for example 300 μm.

Next, a step of forming an epitaxial layer 20 on the silicon carbide substrate 10 is carried out. Here, a description will be made on a chemical vapor deposition (CVD) system which is a crystal growth system used for forming the epitaxial layer 20 on the silicon carbide substrate 10.

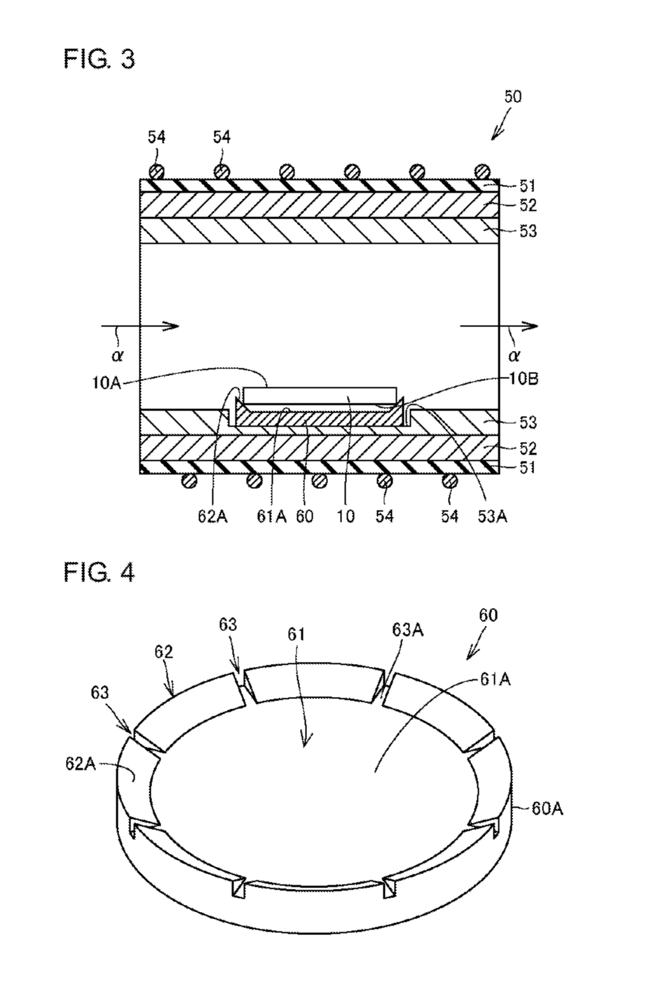

Referring to FIG. 3, a CVD system 50 in this embodiment includes a protective tube 51, a heat-insulating material 52, a heating element 53, and an induction heating coil 54. The heating element 53 has a hollow cylindrical shape. The heating element 53 is, for example, made of carbon (graphite) coated with silicon carbide (SiC) with a thickness of 100 μm. The heat-insulating material 52 has a hollow cylindrical shape whose inner peripheral surface is in contact with the outer peripheral surface of the heating element 53. The protective tube 51 has a hollow cylindrical shape whose inner peripheral surface is contact with the outer peripheral surface the heat-insulating material 52. The protective tube 51 is, for example, made of quartz. The induction heating coil 54 is connected to a power source (not shown) and wound around the outer peripheral surface of the protective tube 51.

A recess 53A is formed in a region including the inner peripheral surface of the heating element 53. The recess 53A can hold a holder 60 which is disk-shaped in plan view. The recess 53A is circularly indented so as to hold the holder 60 which is disk-shaped in plan view. The step the recess 53A is configured, as will be described later, such that, when a silicon carbide substrate 10 is mounted on the holder 60, the second main surface 10B of the silicon carbide substrate 10 is located above the surface of the heating element 53.

Referring to FIG. 4, the holder 60 incudes a tabular base portion 61 and an inclined portion 62 arranged so as to surround the periphery of the base portion 61. The inclined portion 62 is formed so as to protrude toward the first main surface 61A side of the base portion 61. The thickness of the inclined portion 62 increases as the distance from an outer peripheral surface 60A decreases. The inclined portion 62 has an inclined surface 62A which is inclined toward the center of the base portion 61. The inclined portion 62 is provided with a plurality of slits 63 that penetrate the inclined portion 62 in the radial direction. The plurality of slits 63 are formed at equal intervals in the circumferential direction and in a radial manner. A bottom 63A that defines the slit 63 is flush with the first main surface 61A of the base portion 61.

The holder 60 is, for example, made of graphite coated with tantalum carbide (TaC) with a thickness of 20 μm. The diameter of the holder 60 is set so as to correspond to the diameter of the silicon carbide substrate 10. That is, in the case where a silicon carbide substrate 10 with a diameter of 100 mm is held, the diameter of the holder 60 is set to be about 105 to 110 mm. In the case where a silicon carbide substrate 10 with a diameter of 150 mm is held, the diameter of the holder 60 is set to be about 155 to 160 mm. That is, preferably, the diameter of the holder 60 is larger than the diameter of the silicon carbide substrate 10. The recess 53A is configured to correspond to the diameter of the holder 60. That is, preferably, the diameter of the recess 53A is slightly larger than the diameter of the holder 60.

In the method of producing a semiconductor laminate 1 according to this embodiment, subsequent to the step (S10), a substrate loading step, as a step (S20), is carried out. In the step (S20), first, the silicon carbide substrate 10 prepared in the step (S10) is mounted on the holder 60. At this time, referring to FIG. 4. the silicon carbide substrate 10 is mounted on the holder 60 such that the periphery of the silicon carbide substrate 10 is in contact with the inclined surface 62A of the holder 60.

Next, referring to FIG. 3, the holder 60 on which the silicon carbide substrate 10 as been mounted is placed in the recess 53A formed in the heating element 53 of the CVD system 50. At this time, since the silicon carbide substrate 10 is mounted on the holder 60 such that the periphery of the silicon carbide substrate 10 is in contact with the inclined surface 62A of the holder 60, a space is formed between the silicon carbide substrate 10 and the first main surface 61A. More specifically, a space is formed between the second main surface 10B (backside surface), which is opposite the first main surface 10A of the silicon carbide substrate 10 on which the epitaxial layer 20 is to be formed, and the holder 60. That is, the silicon carbide substrate 10 is held by the holder 60 in the state in which the second main surface 10B and the holder 60 are not in contact with each other.

Next, as a step (S30), an epitaxial step is carried out. In the step (S30), an epitaxial layer 20 is formed by epitaxial growth on the first main surface 10A of the silicon carbide substrate 10 (refer to FIG. 1). Specifically, referring to FIG. 3, while the temperature and pressure in the CVD system 50, in which the silicon carbide substrate 10 has been loaded in the step (S20), are being appropriately adjusted, first hydrogen gas is introduced along the arrow a into the CVD system 50. The temperature in the CVD system 50 is adjusted by allowing a high-frequency current to flow through the induction heating coil 54. By allowing the high-frequency current to flow through the induction heating coil 54, the heating element 53 is heated by induction, and the temperature in the CVD system 50 is increased.

The surface of the silicon carbide substrate 10 is etched by heated hydrogen gas. Accordingly, foreign matter and the like adhering to the surface of the silicon carbide substrate 10 are removed. As a result, the first main surface 10A of the silicon carbide substrate 10 is in a clean state suitable for epitaxial growth. Then, source material gases, such as propane and silane and a dopant gas, such as ammonia (NH₃), are introduced into the CVD system 50. The introduced source material gases and dopant gas are thermally decomposed. The chemical reaction between the decomposed source material gases causes epitaxial growth of an epitaxial layer 20 composed of single-crystal silicon carbide on the first main surface 10A. During the epitaxial growth, nitrogen (N) which is part Of the decomposed dopant gas is taken up by the epitaxial layer 20. As a result, a semiconductor laminate 1 which includes the epitaxial layer 20 doped with nitrogen (N) disposed on the silicon carbide substrate 10 is fabricated.

Detailed conditions for epitaxial growth will be shown below. The growth temperature is preferably 1,500° C. to 1650° C. The growth temperature is typically 1600° C. The growth pressure is preferably 60 to 120 hPa. The growth pressure is typically 80 hPa. The hydrogen gas flow rate is preferably 100 to 120 slm. The hydrogen gas flow rate is typically 100 slm. The silane flow rate is typically 40 to 100 sccm. The silane flow rate is typically 90 sccm. The propane flow rate is preferably 10 to 40 sccm. The propane flow rate is typically 30 sccm. The ammonia flow rate is preferably 0.1 to 1 sccm. The ammonia flow rate is typically 0.5 sccm.

Next, as a step (S40), a semiconductor laminate taking-out step is carried out. In the step (S40), the semiconductor laminate 1 fabricated in the step (S30) is taken out of the CVD system 50. Specifically, after the semiconductor laminate 1 fabricated in the step (S30) is cooled to the temperature which allows the semiconductor laminate 1 to be taken out, it is taken out of the CVD system 50. Through the procedure described above, the semiconductor laminate 1 in this embodiment is produced.

In the method of producing a semiconductor laminate according to this embodiment, as described above, etching is performed on the silicon carbide substrate 10 in the step (S30). In general, an epitaxial growth step is carried out in the state in which the second main surface 10B of the silicon carbide substrate 10 and the holder 60 are in contact with each other. Studies by the present inventors have shown that the variation in the roughness of the second main surface 10B is increased in this process. That is, when etching is performed in the state in which the second main surface 10B and the holder 60 are in contact with each other, owing to the warpage of the silicon carbide substrate 10 and the like, a gap is non-uniformly and partially formed between the second main surface 10B and the holder 60. As a result, it is assumed that etching proceeds non-uniformly in the second main surface 10B and the variation in roughness is increased.

In contrast, in the method of producing a semiconductor laminate according to this embodiment, the silicon carbide substrate 10 is held by the holder 60 in the state in which the second main surface 10B and the holder 60 are not in contact with each other. Furthermore, the holder 60 is provided with a plurality of slits 63. Therefore, hydrogen gas that contributes to etching smoothly enters the space between the silicon carbide substrate 10 and the holder 60. As a result, etching uniformly proceeds in the entire second main surface 10B. Therefore, it is possible to suppress a variation in the roughness of the second main surface 10B. Accordingly, it is possible to obtain a semiconductor laminate 1 in which the average value of roughness Ra of the second main surface 10B is 0.1 μm or more and 1 μm or less, and the standard deviation is 25% or less of the average value. That is, a semiconductor laminate 1 in which the roughness of the second main surface 10B is set in a predetermined range can be easily produced without performing polishing, such as chemical mechanical polishing (CMP).

It should be considered that the embodiment disclosed this time is illustrative and non-restrictive in all aspects. The scope of the present invention is defined not by the foregoing description but by the appended claims, and is intended to include all modifications within the meaning and scope equivalent to those of the claims.

### INDUSTRIAL APPLICABILITY

The semiconductor laminate according to the present disclosure can be applied to a semiconductor laminate to be used to manufacture a high-performance semiconductor device.

### REFERENCE SIGNS LIST

1 semiconductor laminate
10 silicon carbide substrate
10A first main surface
10B second main surface
20 epitaxial layer
20A second main surface
20B first main surface
50 CVD system
51 protective tube
52 heat-insulating material
53 heating element
53A recess
54 induction beating coil
60 holder
60A outer peripheral surface
61 base portion
61A first main surface
62 inclined portion
62A inclined surface
63 slit
63A bottom

1. A semiconductor laminate comprising:
a silicon carbide substrate having a first main surface and a second main surface opposite the first main surface; and
an epitaxial layer composed of silicon carbide disposed on the first main surface,
wherein the second main surface has an average value of roughness Ra of 0.1 μm or more and 1 μm or less with a standard deviation of 25% or less of the average value.

2. The semiconductor laminate according to claim 1, wherein the semiconductor laminate has a bow of more than 0 μm and 10 μm or less when the first main surface is placed upward.

3. The semiconductor laminate according to claim 1, wherein the semiconductor laminate has a diameter of 75 mm or more.

4. The semiconductor laminate according to claim 1, wherein the semiconductor laminate has a diameter of 100 mm or more.

5. The semiconductor laminate according to claim 1, wherein the semiconductor laminate has a diameter of 150 mm or more.

6. The semiconductor laminate according to claim 1, wherein the semiconductor laminate has a diameter of 200 mm or more.

7. The semiconductor laminate according to claim 1, wherein the silicon carbide substrate and the silicon carbide epitaxial layer each contain an impurity that generates majority carriers, and
a concentration of the impurity in the silicon carbide substrate is higher than a concentration of the impurity in the epitaxial layer.

8. The semiconductor laminate according to claim 2, wherein the semiconductor laminate has a diameter of 75 mm or more.

9. The semiconductor laminate according to claim 2, wherein the semiconductor laminate has a diameter of 100 mm or more.

10. The semiconductor laminate according to claim 2, wherein the semiconductor laminate has a diameter of 150 mm or more.

11. The semiconductor laminate according to claim 2, wherein the semiconductor laminate has a diameter of 200 mm or more.

12. The semiconductor laminate according to claim 2, wherein the silicon carbide substrate and the silicon carbide epitaxial layer each contain an impurity that generates majority carriers, and
a concentration of the impurity in the silicon carbide substrate is higher than a concentration of the impurity in the epitaxial layer.

13. A semiconductor laminate comprising:
a silicon carbide substrate having a first main surface and a second main surface opposite the first main surface; and
an epitaxial layer composed of silicon carbide disposed on the first main surface,
wherein the second main surface has an average value of roughness Ra of 0.1 μm or more and 1 μm or less with a standard deviation of 25% or less of the average value,
wherein the semiconductor laminate has a bow of more than 0 μm and 10 μm or less when the first main surface is placed upward and has a diameter of 150 mm or more,
wherein the silicon carbide substrate and the silicon carbide epitaxial layer each contain an impurity that generates majority carriers, and
a concentration of the impurity in the silicon carbide substrate is higher than a concentration of the impurity in the epitaxial layer.
